(19) United States
(12) Patent Application Publication
(10) Pub. No.: US 2025/0364247 A1
(43) Pub. Date: Nov. 27, 2025

(54) LASER CRYSTALLIZATION DEVICE AND LASER CRYSTALLIZING METHOD USING THE SAME

(71) Applicant: Samsung Display Co., LTD., Yongin-si (KR)

(72) Inventors: JI-HWAN KIM, Yongin-si (KR); JONGOH SEO, Yongin-si (KR); DONG-MIN LEE, Yongin-si (KR); YU-GWANG JEONG, Yongin-si (KR)

(21) Appl. No.: 19/019,825

(22) Filed: Jan. 14, 2025

(30) Foreign Application Priority Data
May 21, 2024 (KR) 10-2024-0065815

(51) Int. Cl. H01L 21/02; B23K 26/06

(52) U.S. Cl. CPC H01L 21/02678; B23K 26/0643; B23K 26/0648; H01L 21/02532

(57) ABSTRACT

A laser crystallization device includes a laser beam generator which provides a first laser beam onto a substrate, on which a layer to be treated is disposed, a re-reflector positioned in a path of a second laser beam reflected from the layer to be treated, where the re-reflector changes a path of the second laser beam in a direction toward the substrate, and a beam width changer positioned in the path of the second laser beam which is changed by the re-reflector, where the beam width changes a width of the second laser beam in a way such that a third laser beam having a width different from the width of the second laser beam re-enters the substrate.

This application claims priority to Korean Patent Application No. 10-2024-0065815, filed on May 21, 2024, and all the benefits accruing therefrom under 35 U.S.C. § 119, the content of which in its entirety is herein incorporated by reference.

### BACKGROUND

### 1. Field

The disclosure relates to a laser crystallization device and a method of laser crystallization using the laser crystallization device. More specifically, the disclosure relates to a laser crystallization device used in the manufacturing process of an indication device and a method of laser crystallization using the laser crystallization device.

### 2. Description of the Related Art

With the development of information technology, the importance of display devices, which are the medium of connection between users and information, is being highlighted. As a result, the use of display devices such as liquid crystal display devices (“LCD”s), organic light emitting display devices (“OLED”s), and plasma display devices (“PDP”s) is increasing.

A laser crystallization device is an equipment used to manufacture the display device by crystallizing a layer formed on a substrate to be treated with a laser. When the laser is incident on the substrate, a beam may be reflected from the substrate. Demand for the laser crystallization device that has a structure that increases the efficiency of the crystallization process by a beam reflected from the substrate and re-entering the substrate is increasing.

When the reflected beam is re-entering the substrate, an energy profile based on the energy combination of an original beam and the re-entering (re-incident) beam is applied to the layer to be treated.

### SUMMARY

Embodiments provide a laser crystallization device with increased crystallization efficiency.

Other embodiments provide a laser crystallization method using the laser crystallization device.

A laser crystallization device according to an embodiment of the disclosure includes: a laser beam generator which provides a first laser beam onto a substrate, in which a layer to be treated is disposed, a re-reflector positioned in a path of a second laser beam reflected from the layer to be treated, where the re-reflector changes a path of the second laser beam in a direction toward the substrate, and a beam width changer positioned in the path of the second laser beam, which is changed by the re-reflector, where the beam width changer changes a width of the second laser beam in a way such that a third laser beam having a width different from the width of the second laser beam re-enters the substrate.

In an embodiment, the re-reflector may include a prism.

In an embodiment, the re-reflector may include a first plane mirror which primarily reflects the second laser beam reflected from the layer to be treated, and a second plane mirror which secondarily reflects the second laser beam reflected from the first plane mirror in a direction toward the substrate.

In an embodiment, the beam width changer may include an asymmetrical lens with curvature in only one axis.

In an embodiment, the asymmetrical lens may include a cylinder lens or a half-cylinder lens.

In an embodiment, the asymmetrical lens may be provided in plural, and a plurality of the asymmetrical lenses may be disposed in a path of the third laser beam.

In an embodiment, the first laser beam may have a first line beam shape with a short axis and a long axis. In such an embodiment, the third laser beam may have a second line beam shape with a width different from the width of the short axis of the first laser beam.

In an embodiment, the short axis of the first laser beam may have a first beam width, and the short axis of the third laser beam may have a second beam width less than the first beam width.

In an embodiment, a reflectance of the substrate may be defined as a proportion at which the second laser beam is reflected from the substrate relative to a proportion at which the first laser beam is incident to the substrate. In such an embodiment, a ratio of the second beam width to the first beam width may be equal to the reflectance of the substrate.

In an embodiment, an intensity of the first laser beam may be equal to an intensity of the second laser beam.

In an embodiment, the intensity of the third laser beam may have an intensity at which amorphous silicon (a-Si) included in the layer to be treated is crystallized into polysilicon (poly-Si).

In an embodiment, the third laser beam may be is crystallized in a second incident area spaced apart from a first incident area where the first laser beam is incident.

A laser crystallization method according to an embodiment of the disclosure, the method includes: performing a primary crystallization of a layer to be treated by radiating a first laser beam onto a substrate including a layer to be treated, changing a path of a second laser beam reflected from the substrate in a way such that the second laser beam proceeds toward the substrate, changing the second laser beam into a third laser beam having a second beam width different from a first beam width of the first laser beam, and performing a secondary crystallization of the layer to be treated by allowing the third laser beam to re-enter the substrate.

In an embodiment, the changing the second laser beam into a third laser beam may include changing a length of an optical path of the third laser beam to be different from a length of the optical path of the second laser beam.

In an embodiment, the first laser beam, which is radiated to the substrate, has a first line beam shape with a short axis and a long axis, and the third laser beam, which is radiated to the substrate, has a second line beam shape with a width different from the width of the short axis of the first laser beam.

In an embodiment, the second beam width may be less than the first beam width.

In an embodiment, a reflectance of the substrate may be defined as a proportion at which the second laser beam is reflected from the substrate relative to a proportion at which the first laser beam is incident to the substrate, and a ratio of the second beam width to the first beam width may be equal to the reflectance of the substrate.

In an embodiment, an intensity of the third laser beam having the second beam width is substantially the same as an intensity of the first laser beam having the first beam width.

In an embodiment, the intensity of the third laser beam may be an intensity at which amorphous silicon (a-Si) included in the layer to be treated is crystallized into polysilicon (poly-Si).

In an embodiment, the third laser beam may be incident in a second incident area of the substrate spaced apart from a first incident area of the substrate where the first laser beam is incident.

In the laser crystallization device according to embodiments of the disclosure includes,, an effective beam width contributing to crystallization may be increased by changing the width of the third laser beam and allowing the third laser beam to re-enter the substrate as described above. Accordingly, occurrence of vertical line stain defect due to a laser crystallization process may be reduced.

In an embodiment, the re-reflector may include the prism. Accordingly, even when the first laser beam moves during facility operation, the third laser beam also moves along the first laser beam and a beam shape may be maintained. In such an embodiment, a size of the facility including the prism may be reduced compared to a facility including a mirror.

In an embodiment, the re-reflector may include two plane mirrors such that manufacturing cost of the facility may be reduced.

In an embodiment, the beam width changer may include the half-cylinder lens among the asymmetrical lenses. Accordingly, within a limited size facility, the beam width of the third laser beam may be changed.

In an embodiment, the beam width changer may include the cylinder lens among the asymmetric lenses. In such an embodiment, the asymmetrical lenses may be provided in plural. As a result, aberrations may be minimized.

In an embodiment, the first laser beam and the third laser beam have the line beam form having the short axis and the long axis, and the short axis of the first laser beam compared to the shirt axis of the third laser beam may be changed to be equal to the reflectance of the substrate. In such an embodiment, the intensity of the third laser beam may be equal to the intensity of the first laser beam. Here, the intensity of the third laser beam and the intensity of the first laser beam may be the intensity that may crystallize amorphous silicon into polysilicon. Accordingly, the third laser beam may also contribute to crystallization of the layer to be treated, thereby increasing crystallization efficiency.

In an embodiment, the third laser beam may be re-incident in the second incident area spaced apart from the first incident area of the first laser beam. By sufficiently spacing apart the third laser beam from the first laser beam, even if the first laser beam moves during operation of the equipment, the first laser beam and the third laser beam might not overlap, and the anomalous peak might not occur. The abnormal peak may mean a shot having the intensity that may cause abnormal crystallization in the substrate.

In the laser crystallization method according to an embodiment of the disclosure, the secondary crystallization may be performed by a re-incident beam with the changed beam width as described above, such that a stain margin may be enhanced.

### BRIEF DESCRIPTION OF THE DRAWINGS

The above and other features of embodiments of the disclosure will become more apparent by describing in further detail embodiments thereof with reference to the accompanying drawings, in which:

FIG. 1 is a view illustrating a laser crystallization device according to an embodiment of the disclosure.

FIGS. 2 and 3 are views illustrating a first laser beam and a third laser beam incident on the substrate by the laser crystallization device of FIG. 1.

FIG. 4 is a view illustrating a reflectance of the substrate on which the crystallization process is carried out by the laser crystallization device of FIG. 1.

FIGS. 5, 6, 7, and 8 are views illustrating operations of the laser crystallization device of FIG. 1.

FIG. 9 is a view illustrating the laser crystallization device according to another embodiment of the disclosure.

FIG. 10 is a view illustrating the laser crystallization device according to another embodiment of the disclosure.

FIG. 11 is a view illustrating the laser crystallization device according to another embodiment of the disclosure.

FIG. 12 is a flow chart illustrating a laser crystallization method using the laser crystallization device of embodiments of the disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, display devices in embodiments will be described in more detail with reference to the accompanying drawings. The same reference numerals are used for the same components in the drawings, and any repetitive detailed descriptions of the same components will be omitted or simplified.

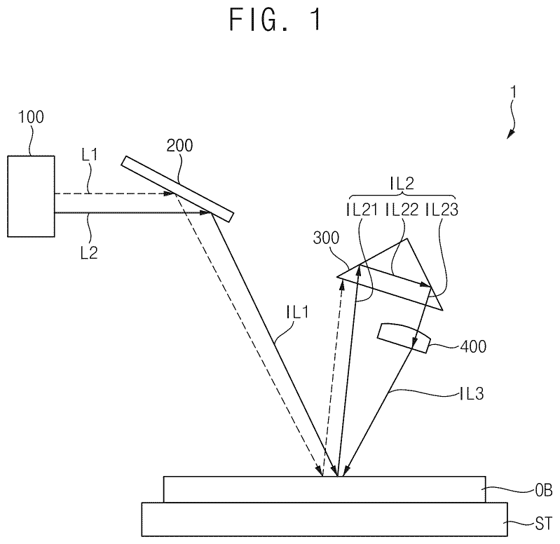

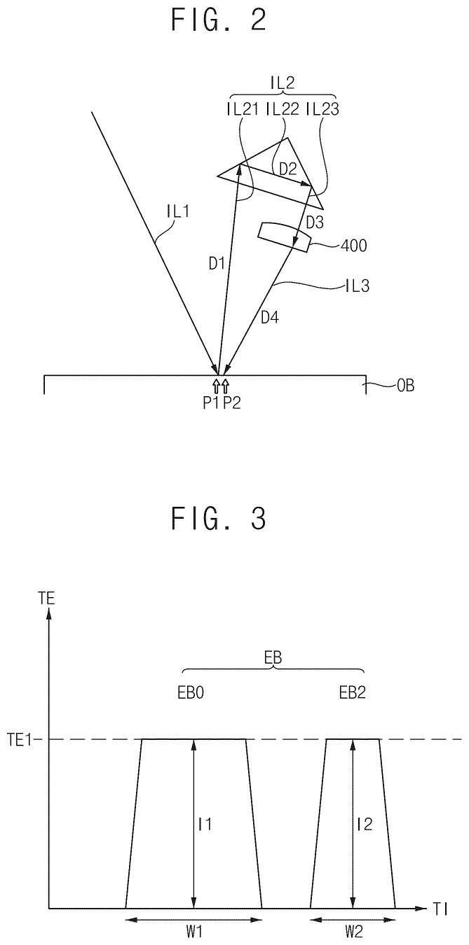

FIG. 1 is a view illustrating a laser crystallization device according to an embodiment of the disclosure. FIGS. 2 and 3 are views illustrating a first laser beam and a third laser beam incident on the substrate by the laser crystallization device of FIG. 1.

Referring to FIGS. 1 and 2, a laser crystallization device 1 according to an embodiment of the disclosure may include a laser beam generator 100, a beam path changer 200, a re-reflector 300, a beam width changer 400, and a stage ST.

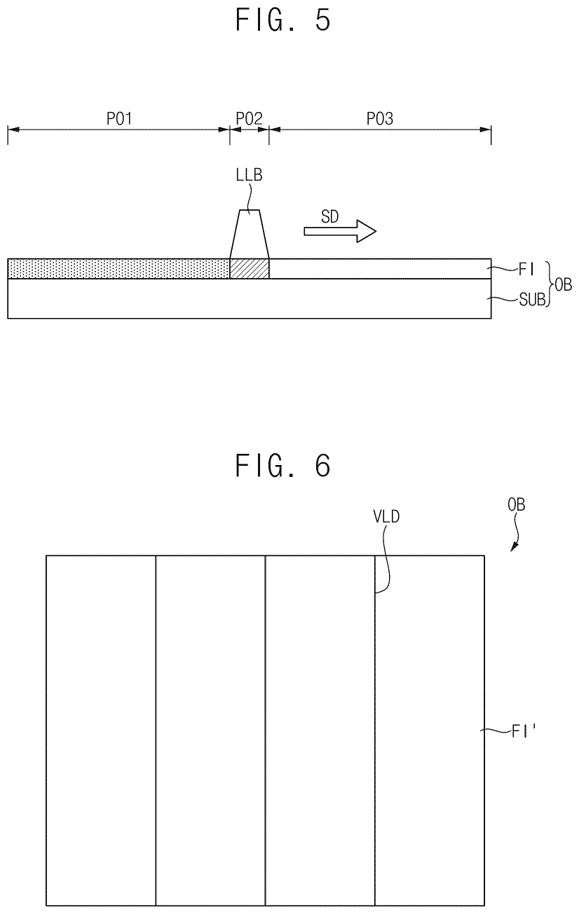

An object to be treated OB may be disposed on the stage ST. The laser crystallization device 1 according to an embodiment of the disclosure may radiate the laser beam to the object to be treated OB disposed on the stage ST (e.g., a substrate SUB including a layer to be treated FI of FIG. 5). In an embodiment, for example, the stage ST may move in one direction or both of the one direction and an opposite direction thereof.

In an embodiment, the laser beam generator 100 may provide a laser beam to the object to be treated OB (e.g., the layer to be treated).

In an embodiment, for example, the beam path changer 200 may be disposed in a path of the laser beam emitted from the laser beam generator 100. In an embodiment, for example, a first raw laser beam L1 emitted from the laser beam generator 100 may move in one direction (e.g., in a horizontal direction). The first raw laser beam L1 may be reflected by the beam path changer 200 such that the beam path of the first raw laser beam L1 may be changed in a direction toward the object to be treated OB.

In an embodiment, for example, an original reflected beam (e.g., a first laser beam IL1) reflected from the beam path changer 200 may be incident to the object to be treated OB at an angle (e.g., the first laser beam IL1 may be incident to have a predetermined angle with a normal line of (or an incident surface of) the object to be treated OB).

In an embodiment, for example, when the original beam (e.g., the first laser beam IL1) is incident at the angle, a reflected beam (e.g., a second laser beam IL2) may be generated from a surface of the object to be treated OB.

In an embodiment, a reflectance of the object to be treated OB may be defined as a proportion at which the second laser beam (e.g., a first second laser beam IL21) is reflected from the object to be treated OB relative to a proportion at which the first laser beam IL1 is incident on the object to be treated OB.

In an embodiment, for example, the object to be treated OB may include silicon. In such an embodiment, the silicon may be melted by the original beam. The molten silicon may have a large reflectance. In such an embodiment, for example, about 60% of the original beam may be reflected. In this case, energy loss may occur, and crystallization efficiency may be reduced.

In an embodiment, the re-reflector 300 may be positioned in a path of the second laser beam (e.g., the first second laser beam IL21) reflected from a surface of the object to be treated OB (e.g., a layer to be treated).

In an embodiment, for example, the re-reflector 300 may change the path of the second laser beam IL2 in a way such that the second laser beam IL2 reflected from the surface of the object to be treated OB may proceed toward the object to be treated OB (e.g., the substrate). In an embodiment, the re-reflector 300 may include a prism. In an embodiment, for

example, the prism may include a first face and a second face crossing the first face. In an embodiment, for example, the firstly second laser beam IL21 may be incident on the first face. A second second laser beam IL22 reflected from the first face may be incident on the second face. A third second laser beam IL23 reflected from the second face may have a beam path in a direction toward the object to be treated OB.

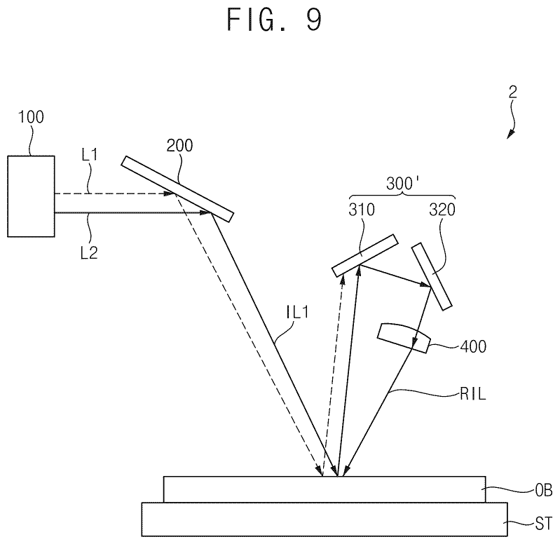

However, the disclosure is not limited thereto. In another embodiment, for example, the re-reflector 300 may include one of other various configurations that may change the path of the second laser beam IL2 in a way such that the second laser beam IL2 reflected from the surface of the object to be treated OB may re-enter the object to be treated OB. In an embodiment, for example, the re-reflector 300 may include a reflective mirror as shown in FIG. 9 (e.g., a first plane mirror 310 and a second plane mirror 320 of FIG. 9).

In such an embodiment, the energy efficiency may be increased by allowing the reflected beam to re-enter the object to be treated OB.

In an embodiment, the beam width changer 400 may be positioned in a path of the second laser beam IL2 (e.g., the thirdly second laser beam IL23) that is re-incident to the processing object OB.

In an embodiment, the beam width changer 400 may allow a third laser beam IL3 generated by changing a width of the second laser beam IL2 to re-enter the object to be treated OB (e.g., the substrate).

In an embodiment, for example, the beam width changer 400 may change a beam width of the re-incident beam in a way such that the re-incident beam (e.g., the third laser beam IL3) incident on the object to be treated OB has a different width than the original beam (e.g., the first laser beam IL1).

In an embodiment, the beam width changer 400 may include an asymmetrical lens with curvature in only one axis. In an embodiment, the asymmetrical lens may include a half-cylinder lens.

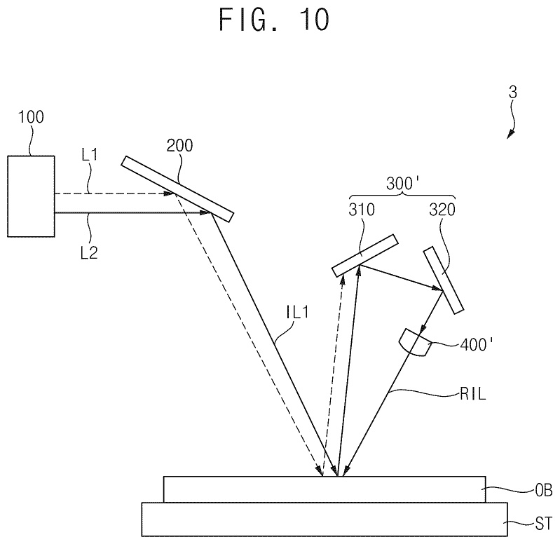

However, the disclosure is not limited thereto. In another embodiment, for example, the beam width changer 400 may include at least one selected from a variety of asymmetric lenses. In another embodiment, for example, the asymmetrical lens may include a cylinder lens as shown in FIG. 10.

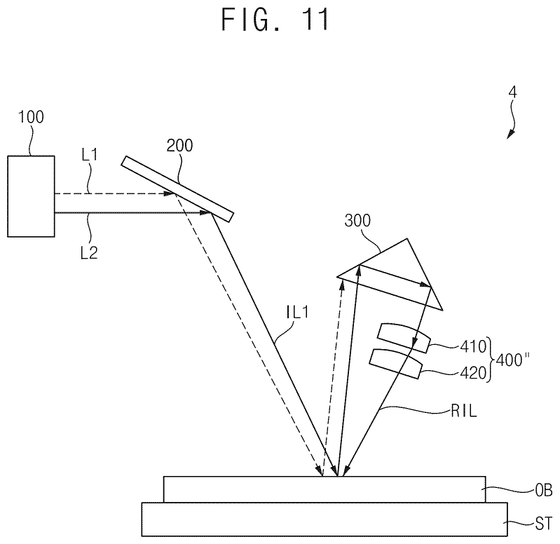

In an embodiment, as shown in FIG. 1, only one lens is included in the beam width changer 400, however, the disclosure is not limited thereto. In another embodiment, for example, the lens included in the beam width changer 400 may be provided in plural (refer to FIG. 11).

In a case of a conventional laser crystallization device (a laser crystallization device according to a comparative embodiment), the prism may not be included. In this case, for example, the raw laser beam emitted from the laser beam generator 100 (e.g., the first raw laser beam L1) may be incident at the angle to the object to be treated OB by the beam path changer 200, and the reflected beam reflected from the object to be treated OB may be reflected from a concave mirror and re-incident to the object to be treated OB.

In this case, for example, if the original beam (e.g., the first raw laser beam L1) is shaken, the raw laser beam (e.g., the first laser beam IL1) may be incident at a different position than a desired position according to a design. In this case, for example, the original beam may be shaken depending on maintenance of the equipment, a curvature of the surface of the object to be treated OB, or the like.

In this case, if the first raw laser beam L1 is incident at a position spaced apart from the desired position according to the design in one direction, a beam shape might not be maintained because the shaken raw laser beam incident to a position spaced apart from an opposite direction to the one direction.

In the case of the laser crystallization device according to the comparative embodiment, a collimating lens may be disposed in the path where the reflected beam and the re-incident beam moved. In this case, the path of the reflected beam may be changed in the direction toward the object to be treated OB by the re-reflector 300 (e.g., the prism), and the re-incident beam may be re-incident to the object to be treated OB by collimating (i.e., preventing divergence) the beam by the collimating lens.

In this case, for example, if the original beam (e.g., the first raw laser beam L1) is shaken, the raw laser beam (e.g., the first laser beam IL1) may be incident at the different position than the desired position according to the design (refer to a second raw laser beam L2)).

In this case, a process margin effect by the overlap of the original beam and the re-reflective beam may be different. In this case, for example, if the original beam and the re-reflective beam overlap excessively, an abnormal peak may occur, and an over-crystallization phenomenon by the abnormal peak may occur. In this case, for example, if the overlap of the original beam and the re-reflective beam is insufficient, the number of additional shots due to the overlap decreases, such that the increase in the process margin due to the re-reflected beam may be small or absent.

In the laser crystallization device according to embodiments of the disclosure (e.g., the laser crystallization device 1 according to an embodiment of FIG. 1, a laser crystallization device 2 according to another embodiment of FIG. 9, a laser crystallization device 3 according to another embodiment of FIG. 10, and/or a laser crystallization device 4 according to another embodiment of FIG. 11), the beam width changer 400 (e.g., the asymmetrical lenses) may be disposed in the moving path of the reflected beam passing the re-reflector (e.g., the prism). In such embodiments, the beam path of the reflected beam may be changed in the direction toward the object to be treated OB by the re-reflector 300, and the re-incident beam may be re-incident to the object to be treated OB with the changed beam width than the original beam.

In an embodiment, the laser crystallization device 1 may satisfy an image condition according to Equation 1 below and a reduction ratio (M) according to Equation 2 below.

$$\frac{1}{f} = \frac{1}{A} + \frac{1}{B} \qquad 〈 Equation 1 〉$$

In Equation 1, ‘f’ denotes a focal length of the asymmetrical lens, ‘A’ denotes a

distance from the object to be treated OB to the asymmetrical lens via the re-reflector 300 (i.e., D1+D2+D3 in FIG. 2), and ‘B’ denotes a distance between the asymmetrical lens and the object to be treated OB (i.e., D4 in FIG. 2))

$$M = \frac{B}{A} = 0.6 \qquad 〈 Equation 2 〉$$

In Equation 2, ‘M’ denotes the reduction ratio.

In such an embodiment, for example, the original beam may correspond to an object, and the reflected beam may correspond to an image. In such an embodiment, the distance from the beam width changer 400 (e.g., the asymmetric lens) to the original beam (i.e., the D1+D2+D3) and the distance from the beam width changer 400 (e.g., the asymmetrical lens) to the reflected beam (i.e., the D4) satisfy the image condition and the reduction ratio, such that the re-incident beam may also be moved in a same direction as a movement direction of the original beam, the beam shape may be maintained, and the re-incident beam whose beam width has been reduced may be re-incident in the same shape at a position adjacent to the incident beam.

In the laser crystallization device 1 according to an embodiment of the disclosure where the prism and the half-cylinder lens are included, a volume may be reduced relative to an equipment including the reflective mirror and other types of lenses.

In an embodiment, as shown in FIG. 2, the third laser beam L3 may be re-incident in the second incident area P2 spaced apart from the first incidence area P1 of the first laser beam IL1.

As described above, in the laser crystallization device according to the comparative embodiment, the process margin effect may differ according to a degree of overlap. For example, if the degree of overlap is insufficient (i.e., less than a predetermined value), the process margin effect is insufficient or absent, and if the degree of overlap is excessive (i.e., greater than a predetermined value), excessive energy is applied, and the super-crystallization phenomenon occurs.

In the laser crystallization device according to embodiments of the disclosure (e.g., the laser crystallization device 1 according to the embodiment of FIG. 1, the laser crystallization device 2 according to the embodiment of FIG. 9, the laser crystallization device 3 according to the embodiment of FIG. 10, and/or the laser crystallization device 4 according to the embodiment of FIG. 11), the re-incident beam (e.g., the third laser beam IL3) may be re-incident in a second incident area P2 sufficiently spaced apart from a first incident area P1 of the original beam (e.g., the first laser beam IL1). The third laser beam IL3 may not generate the additional shot by overlapping with the first laser beam IL1, such that the third laser beam may not overlap the first laser beam IL1, and the super-crystallization may be effectively prevented by having a distance between the first laser beam IL1 and the third laser beam IL3.

FIG. 3 is a graph showing an energy profile of laser beams of the laser crystallization device according to an embodiment. In FIG. 3, an X-axis represents a time TI and a Y-axis represents a temperature TE. In the Y axis of FIG. 3, a first temperature TEI represents a temperature at which the amorphous silicon (“a-SI”) is changed (or crystallized) into the poly silicon (“poly-Si”).

As shown in FIG. 3, in an embodiment, the first laser beam IL1 may have a first line beam shape having a first short axis and a first long axis. The third laser beam IL3 may have a second line beam shape with a width different from (or obtained by changing) the width of the first short axis of the first laser beam IL1.

In an embodiment, the first short axis of the first laser beam IL1 may have a first beam width W1. The second short axis of the third laser beam IL3 may have a second beam width W2 less than the first beam width W1. In other words, the second beam width W2 of the re-incident beam (e.g., the third laser beam IL3) may be less than the first beam width W1 of the original beam (e.g., the first laser beam IL1).

In an embodiment, a second intensity 12 of the third laser beam IL3 may have an intensity at which the amorphous silicon (“a-Si”) included in the layer to be treated is crystallized into the poly silicon (“poly-Si”). In other words, a primary crystallization may be carried out by the original beam (e.g., the first laser beam IL1), and a secondary crystallization may be carried out by the re-incident beam (e.g., the third laser beam IL3).

In an embodiment, a first intensity I1 of the first laser beam IL1 may be the same as the second intensity 12 of the third laser beam IL3. In other words, when the first intensity I1 is the intensity that may contribute to the crystallization, the second intensity 12 may also contribute to the crystallization. In other words, in an embodiment, the second intensity 12 of the third laser beam IL3 may have an intensity at which the amorphous silicon (“a-Si”) included in the object to be treated (e.g., the layer to be treated) is crystallized into the poly silicon (“poly-Si”).

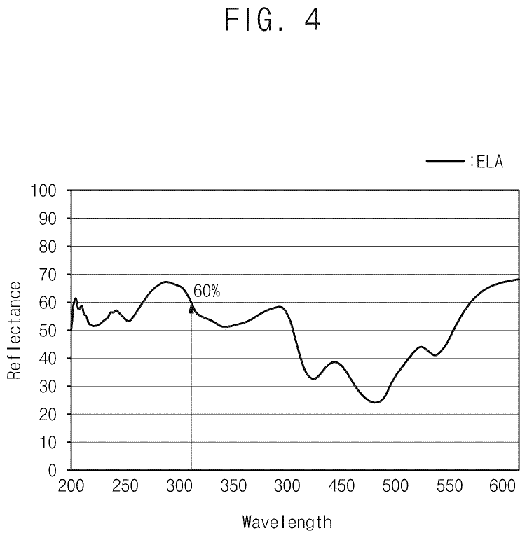

FIG. 4 is a view illustrating a reflectance of the substrate on which the crystallization process is carried out by the laser crystallization device of FIG. 1.

Referring to FIGS. 3 and 4, in an embodiment, the second beam width W2 relative to the first beam width W1 (i.e., a ratio of the second beam width W2 to the first beam width W1) may be a same as the reflectance. For example, a wavelength of the laser beam used for the crystallization may be about 308 nanometers (nm). The object to be treated OB may include the silicon (Si). In this case, if the excimer laser annealing (“ELA”) process is carried out using the laser beam having the wavelength, the reflectance of the object to be treated OB may be about 60%.

Accordingly, as described above with reference to Equation 2, for example, the second beam width W2 relative to the first beam width W1 may be set to about 60%. However, the disclosure is not limited thereto. In another embodiment, for example, where the reflectance is changed, the second beam width W2 may be set relative to the first beam width W1 to match a magnitude of the reflectance. In other words, in Equation 2, the value of 0.6 may be changed.

FIGS. 5, 6, 7, and 8 are views illustrating operations of the laser crystallization device of FIG. 1.

Referring to FIG. 5, an embodiment of the laser crystallization device may be used to perform an ELA process. The ELA process may be a heat treatment process by applying a high-voltage discharge to a gas laser source to generate instantaneous high laser-energy.

For example, the ELA process may be carried out using a line beam LLB (e.g., the first line beam and the second line beam).

For example, the object to be treated OB may include a substrate SUB and a layer to be treated FI. The layer to be treated FI may be heat treated as the laser scans thereon.

For example, in a first region PO1 where the line beam LLB has completed scanning, the layer to be treated FI may include the polysilicon (“poly-Si”). In a second region PO2 where the heat treatment is in progress, the silicon may be in a molten state. After the completion of the heat treatment, the line beam LLB may move to a third region PO3.

For example, the stage ST of FIG. 1 may move along a scan direction SD. Accordingly, an area where the heat treatment is carried out in the layer to be treated FI on the substrate SUB (e.g., the second region PO2) may be changed. However, the disclosure is not limited thereto. In an embodiment, for example, a device that grips the substrate SUB may move only the substrate, or a device that generates the line beam LLB may move.

Referring to FIGS. 5 and 6, the line beam LLB may move along the scan direction SD and scan, such that a vertical line stain defect VLD may be occurred in the layer to be treated FI′.

When the ELA process is performed with the line beam LLB, the vertical line stain defect VLD may occur due to energy fluctuations. The vertical line stain defect VLD may be enhanced with a laser induced periodic surface structure (“LIPSS”). For example, as the number of shots increases, an arrangement of crystals may follow an arrangement of optical interference. Accordingly, the vertical line stain defect VLD may be enhanced, and then the stain margin may be increased.

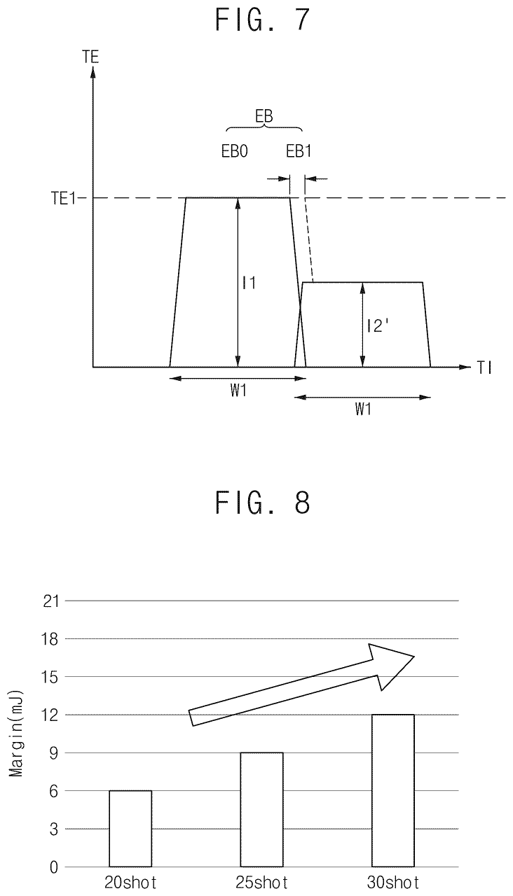

FIG. 7 is a graph showing an energy profile of laser beams of the laser crystallization device according to the comparative embodiment. Referring to FIGS. 1 and 7, the X-axis represents the time TI, and the Y-axis represents the temperature TE. In FIGS. 3 and 7, the first temperature TE1 of the Y-axis may be the temperature at which the amorphous silicon (“a-Si”) is crystallized into the poly silicon (“poly-Si”).

In the case of the laser crystallization device according to the comparative embodiment, the original beam (e.g., the first laser beam L1) and the re-incident beam (e.g., the third laser beam L3) may overlap.

For example, the first beam width W1 of the original beam may be about 470 micrometers, and the scan pitch may be about 20 micrometers, so that about 25 overlapping shots may be provided to the object to be treated OB.

In a case of recycling of the re-incident beam, about 28 overlapping shots may be provided to the object to be treated OB by an effective shot by the original beam EBO and an effective shot by the re-incident beam EB1. In other words, by recycling the re-incident beam, the number of effective shots of about 3 shots may be increased, and the stain margin improvement effect may be greater.

As shown in FIG. 7, in the case of the laser crystallization device according to the comparative embodiment, the beam width of the re-incident beam may be equal to the first beam width W1, which is the beam width of the original beam. The original beam may be reflected about 60%, such an intensity I2′ of the re-incident beam may be about 60% of an intensity I1′ of the original beam.

With the intensity I2′ of the re-incident beam, the number of effective shots EB1 with the temperature TE1 contributing to the crystallization process may be only about 3 shots.

However, as shown in FIG. 3, in the case of the laser crystallization device according to embodiments of the disclosure, the second beam width W2 of the re-incident beam relative to the first beam width W1 of the original beam may be set to match the reflectance. Accordingly, the second intensity I2 of the re-incident beam may be equal to the first intensity I1 of the original beam. Accordingly, in such an embodiment, by changing the beam width, the number of effective shots EB2 in which the re-incident beam contributes to the crystallization may be about 14 to about 15 shots is increased, and the stain margin improvement effect may be greater.

In such an embodiment, as described above, even if the original beam and the re-incident beam are spaced apart (i.e., not overlapped), the number of effective shots may increase, and the stain margin effect may be greater.

Referring to FIG. 8, an X-axis represents the number of shots, and a Y-axis represents a stain margin range. A unit of the stain margin range is millijoules (mJ).

The stain margin range showed a tendency proportional to the number of shots. For example, at about 20 shots the margin was about 6 mJ, at about 25 shots the margin was about 9 mJ, and at about 30 shots the margin was about 12 mJ.

As described above, the laser crystallization device according to the comparative embodiment may increase the number of effective shots by about 3 shots. The laser crystallization device according to embodiments of the disclosure may increase the number of effective shots by about 14 to about 15 shots. Accordingly, by using the laser crystallization device according to embodiments of the disclosure, that the stain margin effect is greater may be confirmed.

The effective margin range of the laser crystallization device according to embodiments of the disclosure may be greater as the number of effective shots increases. As the effective margin range is greater, the laser crystallization device according to embodiments of the disclosure may be less sensitive to a process condition. For example, as the process condition is sensitive, the stain may occur greater with the change in the energy density, but as the sensitivity of the process condition decreases, although the change in the energy density, the stain level might not be changed or changed minimally.

FIG. 9 is a view illustrating the laser crystallization device according to another embodiment of the disclosure. FIG. 10 is a view illustrating the laser crystallization device according to another embodiment of the disclosure. FIG. 11 is a view illustrating the laser crystallization device according to another embodiment of the disclosure.

Hereinafter, any repetitive detailed descriptions of the same or like elements as those of the laser crystallization device described above with reference to FIGS. 1 to 8 will be omitted or simplified.

Referring to FIGS. 1, 5, and 9, in an embodiment, the re-reflector 300 may include a plurality of mirrors 300′ instead of the prism. In an embodiment, the plurality of mirrors 300′ may include the first plane mirror 310 which firstly reflects the second laser beam IL2 reflected from the layer to be treated FI, and the second plane mirror 320 which secondary reflects the second laser beam IL2 reflected from the first plane mirror 310 in the direction toward the substrate SUB. In such an embodiment, a cost of manufacturing an equipment may be reduced by including the mirror, which is typically cheaper than the prism. A re-incident beam RIL reflected from the mirror may re-incident to the object to be treated OB with the reduced beam width than the first laser beam IL1.

Referring to FIG. 10, in an embodiment, a beam width changer 400′ may include a variety of asymmetric lenses. In an embodiment, for example, the asymmetric lens may include the cylinder lens. If the lens deviates from an optical axis of the lens, an aberration may occur. In such an embodiment where the beam width changer 400′ includes the cylinder lens, the optical axis of the reflected beam and the optical axis of the re-incident beam may be configured to be almost parallel, such that an occurrence of the aberrations may be minimized.

In such an embodiment, a beam between a re-reflector 300′ (e.g., the second plane mirror 320) and the beam width changer 400′ and a beam between the beam width changer 400′ and the object to be treated OB may be positioned in an about straight line. In such an embodiment, a position of the re-reflector 300′ (e.g., the second plane mirror 320) may be adjusted. In an embodiment, for example, to position in the straight line the beams, the second plane mirror 320 may have a greater gap with the first plane mirror 310.

The disclosure is not limited thereto. In another embodiment, for example, the re-reflector 300′ may correspond to the re-reflector 300 of FIG. 1 (e.g., the prism). In such an embodiment, a gap between the two reflective planes included in the prism may be adjusted. In another embodiment, for example, a lens with a shape without the aberrations may be disposed.

Referring to FIG. 11, in an embodiment, the lens 400′ included in the beam width changer 400 (e.g., a first lens 410 and a second lens 420) may be provided in plural. In such an embodiment, as described above, the lenses 400′ may be asymmetrical lenses. In an embodiment, the asymmetrical lens may include the half-cylinder lens. In an embodiment, the asymmetrical lens may include the cylinder lens.

In an embodiment, for example, light passing through the lens may not be concentrated in any one focus, and a spherical aberration problem may occur, in which multiple focal points are formed. For example, light passing through an outside of the lens may be in focus in front of the light passing through a center of the lens. In such an embodiment, the plurality of lenses 400′ may be disposed to reduce the aberration.

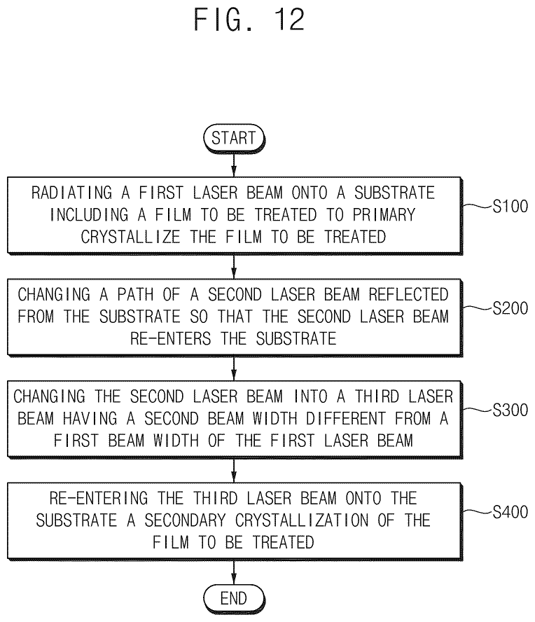

FIG. 12 is a flow chart illustrating a laser crystallization method using the laser crystallization device of embodiments of the disclosure.

Hereinafter, descriptions that overlap with the laser crystallization device described with reference to FIGS. 1 to 11 will be omitted or simplified.

Referring to FIGS. 1, 5, 9, 10, 11, and 12, the laser crystallization method according to an embodiment of the disclosure may include the following processes.

In such an embodiment, the first laser beam IL1 may be radiated onto the substrate SUB including the layer to be treated FI to primary crystallize the layer to be treated FI (S100).

That is, a primary crystallization of the layer to be treated FI may be performed by radiating the first laser beam IL1 onto the substrate SUB including the layer to be treated FI. In an embodiment, in the step i), the first laser beam IL may be irradiated to the substrate SUB in the first line beam shape having the short axis and the long axis.

In such an embodiment, the path of the second laser beam IL2 may be changed in a way such that the second laser beam IL2 reflected from the substrate SUB may proceed toward the substrate SUB (S200).

In such an embodiment, the second laser beam LI2 may be changed to the third laser beam IL3 with the second beam width W2 different from the first beam width W1 of the first laser beam LI1 (S300).

In an embodiment, the length of the optical path D4 of the third laser beam IL3 may be changed to be different from the length of the optical path D1+D2+D3 of the second laser beam IL2 (refer to FIG. 2).

In an embodiment, the second beam width W2 relative to the first beam width W1 may be changed in a way such that the second beam width W2 relative to the first beam width W1 is equal to the reflectance of the substrate SUB (refer to FIG. 4). In an embodiment, the second beam width W2 may be less than the first beam width W1. In an embodiment, the second beam width W2 may be changed in a way such that the second intensity I2 of the third laser beam LI3 is equal to the first intensity I1 of the first laser beam LI1. In an embodiment, the second intensity I2 may be changed to the intensity at which the amorphous silicon included in the layer to be treated FI is crystallized into the poly silicone.

In such an embodiment, the third laser beam LI3 may secondarily crystallize the layer to be treated FI by re-entering (being re-incident onto) the substrate SUB (S400). That is, a second crystallization of the layer to be treated FI may be performed by allowing the third laser beam LI3 to re-enter the layer to be treated FI.

In an embodiment, the third laser beam L3 may be radiated to the substrate SUB in the shape of the second line beam with the changed width of the short axis (e.g., the first beam width W1). In an embodiment, the layer to be treated FI may be secondarily crystallized in the second incident area P2 spaced apart from the first incident area P1 of the first laser beam LI1 (refer to FIG. 2).

As the secondary crystallization is performed by the re-incident beam with reduced beam width, the stain margin may be enhanced.

Using the laser crystallization device and the laser crystallization method using the laser crystallization device according to the embodiments of the disclosure, not only the original beam but also the re-reflective beam as the crystallization proceeds, a line by the re-reflective beam may be found outside the scan area at the end of the scan direction. In the case of scanning using only the original beam, the heat treatment may be applied only within the scan area, but in the case of the laser crystallization device and the laser crystallization method using the laser crystallization device according to the embodiments of the disclosure, trace due to the additional heat treatment by the re-reflective beam may be checked at the outside the scan area.

The laser crystallization device and the laser crystallization method using the laser crystallization device according to the embodiments of the disclosure may be confirmed by laser shot test. In an embodiment, for example, as a result of the laser shot test, original beam and additional re-incident beam having the same intensity as the original beam may be checked. In another embodiment, for example, the re-incident beam with the reduced beam width than the original beam may be checked.

The substrate on which the crystallization process has been completed by using the laser crystallization device and the laser crystallization method using the laser crystallization device according to the embodiments of the disclosure may allow the stain to be examined by eyes. In addition, the substrate may allow the stain to be examined by method of 2TR (transistor) image quality comparison (e.g., operating condition without applying an organic light emitting device (OLED) compensation circuit, a condition that no stain reduction by the compensation circuit). The substrate has minimal or no stain using may be checked.

The laser crystallization device and the laser crystallization method in the embodiments may be used to manufacture a display device included in a computer, a notebook, a mobile phone, a smartphone, a smart pad, a portable media player (“PMP”), a personal digital assistance (“PDA”), an MP3 player, or the like.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A laser crystallization device comprising:
a laser beam generator which provides a first laser beam onto a substrate, on which a layer to be treated is disposed;
a re-reflector positioned in a path of a second laser beam reflected from the layer to be treated, wherein the re-reflector changes a path of the second laser beam in a direction toward the substrate; and
a beam width changer positioned in the path of the second laser beam which is changed by the re-reflector, wherein the beam width changer changes a width of the second laser beam in a way such that a third laser beam having a width different from the width of the second laser beam re-enters the substrate.

2. The laser crystallization device of claim 1, wherein the re-reflector includes a prism.

3. The laser crystallization device of claim 1, wherein,
the re-reflector includes a first plane mirror which primarily reflects the second laser beam reflected from the layer to be treated, and a second plane mirror which secondarily reflects the second laser beam reflected from the first plane mirror in a direction toward the substrate.

4. The laser crystallization device of claim 1, wherein the beam width changer includes an asymmetrical lens with a curvature in only one axis.

5. The laser crystallization device of claim 4, wherein the asymmetrical lens includes a cylinder lens or a half-cylinder lens.

6. The laser crystallization device of claim 4, wherein
the asymmetrical lens is provided in plural, and
a plurality of the asymmetrical lenses is disposed in a path of the third laser beam.

7. The laser crystallization device of claim 4, wherein,
the first laser beam has a first line beam shape with a short axis and a long axis, and
the third laser beam has a second line beam shape with a width different from the width of the short axis of the first laser beam.

8. The laser crystallization device of claim 7, wherein,
the short axis of the first laser beam has a first beam width, and
the short axis of the third laser beam has a second beam width less than the first beam width.

9. The laser crystallization device of claim 8, wherein,
a reflectance of the substrate is defined as a proportion at which the second laser beam is reflected from the substrate relative to a proportion at which the first laser beam is incident to the substrate, and
a ratio of the second beam width to the first beam width is equal to the reflectance of the substrate.

10. The laser crystallization device of claim 1, wherein an intensity of the first laser beam is equal to an intensity of the second laser beam.

11. The laser crystallization device of claim 1, wherein the intensity of the third laser beam has an intensity at which amorphous silicon included in the layer to be treated is crystallized into polysilicon.

12. The laser crystallization device of claim 1, wherein the third laser beam is incident in a second incident area spaced apart from a first incident area where the first laser beam is incident.

13. A laser crystallization method, the method comprising:
performing a primary crystallization of a layer to be treated by radiating a first laser beam onto a substrate on which a layer to be treated is disposed;
changing a path of a second laser beam reflected from the substrate in a way such that the second laser beam proceeds toward the substrate;
changing the second laser beam into a third laser beam having a second beam width different from a first beam width of the first laser beam; and
performing a secondary crystallization of the layer to be treated by allowing the third beam to re-enter the substrate.

14. The laser crystallization method of claim 13, wherein the changing the second laser beam into the third laser beam includes changing a length of an optical path of the third laser beam to be different from a length of the optical path of the second laser beam.

15. The laser crystallization method of claim 13, wherein,
the first laser beam, which is radiated to the substrate, has a first line beam shape with a short axis and a long axis, and
the third laser beam, which is radiated to the substrate, has a second line beam shape with a width different from the width of the short axis of the first laser beam.

16. The laser crystallization method of claim 15, wherein the second beam width is less than the first beam width.

17. The laser crystallization method of claim 13, wherein,
a reflectance of the substrate is defined as a proportion at which the second laser beam is reflected from the substrate relative to a proportion at which the first laser beam is incident to the substrate, and
wherein a ratio of the second beam width to the first beam width is equal to the reflectance of the substrate.

18. The laser crystallization method of claim 13, wherein an intensity of the third laser beam having the second beam width is substantially the same as an intensity of the first laser beam having the first beam width.

19. The laser crystallization method of claim 18, wherein the intensity of the third laser beam is an intensity at which amorphous silicon (a-Si) included in the layer to be treated is crystallized into polysilicon (poly-Si).

20. The laser crystallization method of claim 13, wherein the third laser beam is incident in a second incident area of the substrate spaced apart from a first incident area of the substrate where the first laser beam is incident.
